(19) United States
(12) Patent Application Publication
(10) Pub. No.: US 2021/0147646 A1
(43) Pub. Date: May 20, 2021

(54) PREPREG, LAMINATED AND PRINTED CIRCUIT BOARD THEREOF

(71) Applicant: ITEQ CORPORATION, HSINCHU COUNTY (TW)

(72) Inventors: MING LIU, Wuxi City (CN); TSUNG-LIEH WENG, Hsinchu County (TW); SHAO-JIE YUAN, Wuxi City (CN); KAI-YANG CHEN, HSINCHU COUNTY (TW); TA-YUAN YU, HSINCHU COUNTY (TW)

(21) Appl. No.: 16/822,013

(22) Filed: Mar. 18, 2020

(30) Foreign Application Priority Data
Nov. 18, 2019 (CN) 201911127763.1

(51) Int. Cl. C08J 5/24; B32B 5/02; B32B 15/14; B32B 15/20; H05K 1/03; H05K 1/09

(52) U.S. Cl. CPC C08J 5/24; B32B 5/022; B32B 15/14; B32B 15/20; H05K 1/0366; B32B 2260/046; C08J 2363/00; B32B 2262/0253; B32B 2250/40; B32B 2260/021; H05K 1/09

(57) ABSTRACT

A prepreg, a laminated board, and a printed circuit board thereof are provided. The prepreg includes a halogen-free epoxy resin composition and a partially cured non-woven reinforcing material impregnated therein. The non-woven reinforcing material has a dielectric strength of 1.5 to 4.8 and a loss factor that is less than 0.003 at 10 GHz, and the halogen-free epoxy resin composition includes: (a) 100 parts by weight of a halogen-free naphthalene type epoxy resin, (b) 10 to 25 parts by weight of a DOPO modifying curing agent, (c) 25 to 45 parts by weight of a cyanate resin, (d) 35 to 60 parts by weight of bismaleimide, (e) 45 to 65 parts by weight of a non-DOPO flame retardant, and (f) 0.5 to 15 parts by weight of a curing accelerator.

### CROSS-REFERENCE TO RELATED PATENT APPLICATION

This application claims the benefit of priority to China Patent Application No. 201911127763.1, filed on Nov. 18, 2019 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a prepreg, a laminated board, and a printed circuit board, and more particularly to a prepreg, a laminated board, and a printed circuit board including a halogen-free epoxy resin composition.

### BACKGROUND OF THE DISCLOSURE

A printed circuit board (PCB) is usually a composite material formed by impregnating a reinforced material in a polymer material, and then one or both sides of the composite material are clad with metal layer(s) to form a laminate for PCB applications.

In general, strengthening materials are mainly woven glass materials, such as low dielectric constant (Dk) glass, E-type glass, R-type glass, ECR-type glass, S-type glass, C-type glass, and Q-type glass. However, woven glass materials and polymer materials are heterogeneous materials, which lead to a delay of the signal. This phenomenon is known as “skew” in digital engineering parlance.

Furthermore, the existing polymer materials include a halogen-containing flame retardant (particularly a bromine-containing flame retardant) such as tetrabromocyclohexane, hexabromocyclodecane, 2,4,6-tris(tribromophenoxy))-1,3,5-triazine and so on. Halogen-containing flame retardant has the advantages of possessing better flame retardancy and requiring less usage amounts. However, manufacturing, using, recycling, or discarding halogen products may easily result in environmental pollution. In addition, when burning halogen-containing electronic equipment, corrosive, toxic gases and fumes may be generated, and carcinogens such as dioxins, dibenzofuran, and other carcinogens are detected after the halogen-containing electronic equipment is burnt. Thus, halogen-free flame retardant printed circuit board has become the key for development in this field.

In summary, improving the above defects and maintaining the characteristics such as the heat resistance, flame retardancy, low dissipation factor, low hygroscopicity, high crosslinking density, high glass transition temperature, high bondability, appropriate thermal expansion, and so on are the important issues when developing and manufacturing the printed circuit board.

### SUMMARY OF THE DISCLOSURE

In response to the above-referenced technical inadequacies, the present disclosure provides a prepreg, laminated board, and printed circuit board including a halogen-free epoxy resin composition and non-woven reinforcing material.

In one aspect, the present disclosure provides a prepreg, including: a non-woven reinforcing material and a halogen-free epoxy resin composition, and the non-woven reinforcing material is impregnated with the halogen-free epoxy resin composition, and is partially cured. The non-woven reinforcing material has a dielectric constant of from 1.5 to 4.8 and a dissipation factor at 10 GHz below 0.003, and the halogen-free epoxy resin composition includes: (a) 100 parts by weight of a halogen-free naphthalene based epoxy resin, (b) 10 to 25 parts by weight of DOPO modified curing agent, (c) 25 to 45 parts by weight of cyanate resin, (d) 35 to 60 parts by weight of bismaleimide, (e) 45 to 65 parts by weight of non-DOPO flame retardant, and (f) 0.5 to 15 parts by weight of accelerating agent.

In another aspect, the present disclosure provides a laminated board, including a resin substrate that includes a plurality of cured prepreg, and at least one metal foil layer disposed on at least one surface of the resin substrate.

In yet another aspect, the present disclosure provides a printed circuit board formed by patterning the metal foil layer of the laminated board.

One of the advantages of the present disclosure is that the present disclosure can provide better glass transition temperature and is skew-free by using the technical feature of “a non-woven reinforcing material having a dielectric constant of from 1.5 to 4.8 and a dissipation factor at 10 GHz below 0.003” and “45 to 65 parts by weight of non-DOPO flame retardant.”

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a sectional view of a prepreg of the present disclosure.

FIG. 2 is a sectional view of a laminated board of the present disclosure.

FIG. 3 is a sectional view of a printed circuit board of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

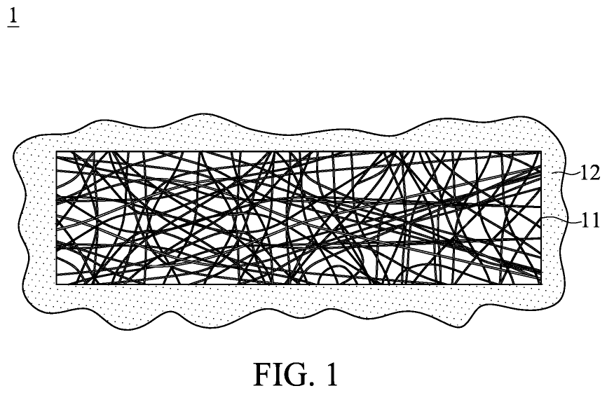

Referring to FIG. 1, the present disclosure provides a prepreg 1 that includes a non-woven reinforcing material 11 and a halogen-free epoxy resin composition 12, and the non-woven reinforcing material 11 is impregnated with the halogen-free epoxy resin composition 12.

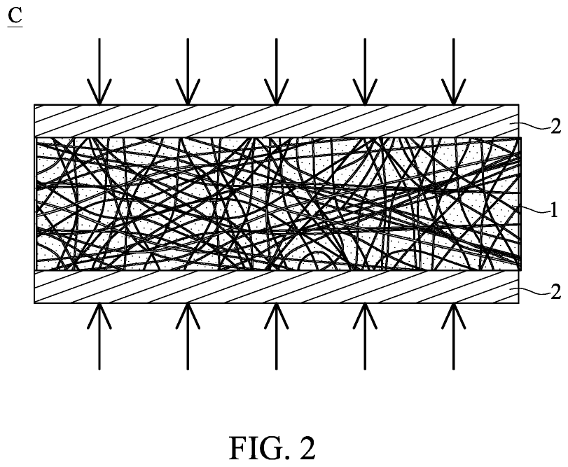

Referring to FIG. 2, the present disclosure further provides a laminated board C, including: at least a resin substrate 1 and at least one metal foil layer 2, 2′. The resin substrate 1 is formed by curing the prepreg 1 as shown in FIG. 1, and the metal foil layers 2, 2′ are disposed on the surface of the prepreg 1, and then pressured to form the laminated board C. In addition, according to an embodiment of the present disclosure, the laminated board C includes a plurality of resin substrate 1, and is laminated in the order of the metal foil layer 2, the plurality of resin substrate 1, and the metal foil layer 2′. In other words, the plurality of resin substrate 1 is sandwiched between the metal foil layer 2 and the metal foil layer 2′. The metal foil layers 2, 2′ can be copper foils. The pressuring condition includes: pressure from 200 to 220 psi, temperature from 200 to 250° C., and time from 1 to 3 hours.

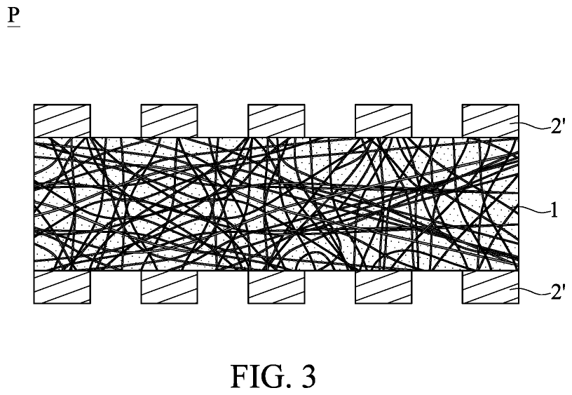

Referring to FIG. 3, the laminated board C of the present disclosure can be applied on a printed circuit board P, which is formed by patterning the metal foil layers 2, 2′ of the laminated board C. For example, the metal foil layers 2, 2′ can be patterned by a lithographic etching process to further form a printed circuit layer.

Specifically, the coefficient of thermal expansion of semiconductor components is 3 to 6 ppm/° C. The coefficient of thermal expansion of the naphthalene based epoxy resin is smaller than that of a printed wiring board for conventional semiconductor plastic packages. Therefore, when the semiconductor plastic package undergoes thermal shock, the semiconductor plastic package may be warped due to the difference in coefficient of thermal expansion between the semiconductor component and the printed wiring board, and also, connection defects may further occur between the semiconductor component and the printed wiring board.

When a rigid fused ring structure is introduced into the epoxy skeleton, the movement of the epoxy ring chain is weakened, the free-volume is reduced, the rigidity of the polymer chain is increased, the bulk density of the cured epoxy resin is enhanced, and the heat resistance of the cured epoxy is improved significantly. The fused ring structure epoxy resin can be categorized as naphthalene, anthracene, and pyrene epoxy resin according to the structure thereof. Anthracene and pyrene epoxy resin have long reaction time, low yield, with lower reactivity and raw materials thereof are expensive. As the size of the anthracene ring and pyrene ring is larger, the crosslinking density of the resin is highly affected. Thus, the anthracene ring and pyrene ring have limited performance in improving the heat resistance of epoxy resin. In contrast, the naphthalene ring compounds have high reactivity and heat resistance, which is suitable for epoxy resin composition.

Specifically, the naphthalene ring structure of a naphthalene based epoxy resin has high heat resistance, low coefficient of thermal expansion (CTE), and low moisture absorption. Preferably, the halogen-free naphthalene based epoxy resin is at least one selected from the group consisting of di-naphthalene based epoxy resin, tetra-naphthalene based epoxy resin and oxazolidone-containing di-naphthalene based epoxy resin, for example, as shown in the following structure:

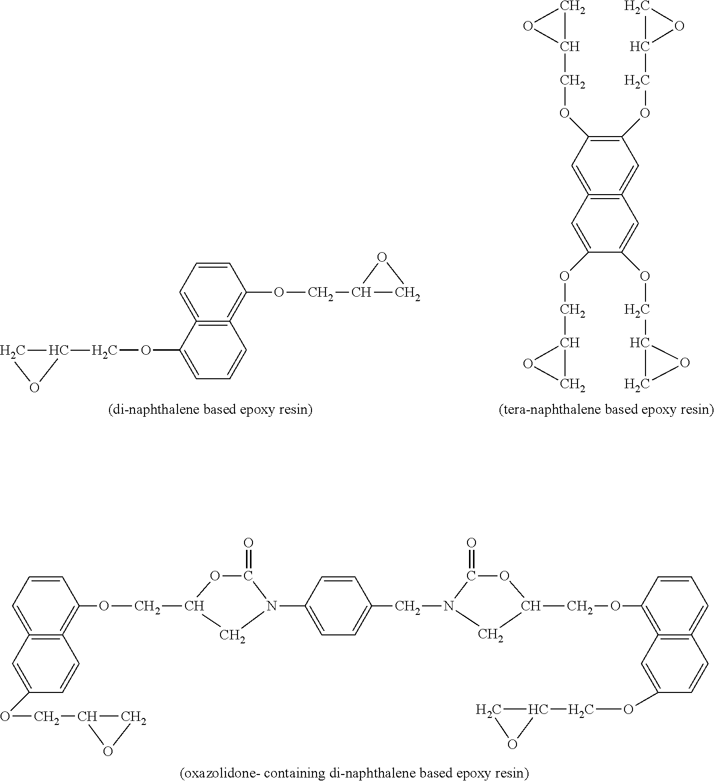

Further, 9,10-dihydro-9-oxa-10-phosphaphenanthrene-10-oxide (DOPO) modified curing agent in the present disclosure is used to react with an epoxy resin as a curing agent. The modified curing agent provides high thermal stability, low dielectric properties, and enhances the flame retardant effect. The DOPO modified curing agent of the present disclosure is at least one selected from the group consisting of DOPO-hydroquinone resin, DOPO-naphthalene diol resin, DOPO-novolac resin and DOPO-bisphenol novolac resin. Furthermore, the DOPO-containing bisphenol novolac resin is at least one selected from the group consisting of DOPO-containing bisphenol A novolac resin (DOPO-BPAN), DOPO-containing bisphenol F novolac resin (DOPO-BPFN), and DOPO-containing bisphenol S novolac resin (DOPO-BPSN)

The cyanate resin increases the reactive functional groups in the resin structure, further improves the crosslinking density of the epoxy cured compounds, decreases the free-volume of the halogen-free epoxy resin composition, and improves the heat resistance; however, the cyanate resin in the present disclosure is not limited thereto. For example, the cyanate resin may be polyfunctional aliphatic isocyanate compounds, polyfunctional alicyclic isocyanate compounds, polyfunctional aromatic isocyanate compounds such as trimethylene diisocyanate, tetramethylene diisocyanate, methylene diisocyanate, pentamethylene diisocyanate, 1,2-propylene diisocyanate, 1,3-butylene diisocyanate, dodecamethylene diisocyanate, 2,4,4-trimethyl Hexamethylene diisocyanate and the like, 1,3-cyclopentene diisocyanate, 1,3-cyclohexane diisocyanate, 1,4-cyclohexane diisocyanate, isophorone diisocyanate, hydrogenated diphenylmethane Diisocyanates, hydrogenated xylylene diisocyanate, hydrogenated tolylene diisocyanate, hydrogenated tetramethylxylylene diisocyanate, phenylene diisocyanate, 2,4-tolylene diisocyanate, 2,6-tolylene diisocyanate, 2,2′-diphenylmethane diisocyanate, 4,4′-diphenylmethane diisocyanate, 4,4′-toluidine diisocyanate, 4,4′-diphenyl ether diisocyanate, 4,4′-diphenyldiisocyanate, 1,5-naphthalene diisocyanate, benzene Methylene diisocyanate, and the like.

The bismaleimide is mainly a compound containing two maleimide groups in the molecule, and it is also possible to select prepolymer of bismaleimide compounds, or bis prepolymer of maleimide compounds and amine compounds, but the present disclosure is not limited thereto. Preferably, the bismaleimide is at least one selected from the group consisting of bis(4-phenylmaleimide)methane, 2,2-bis(4-(4-phenoxymaleimide)-phenyl)propane, bis(3,5-dimethyl-4-phenylmaleimide)methane, bis(3-ethyl-5-methyl-4-phenylmaleimide), and (3,5-diethyl-4-phenylmaleimide)methane.

Preferably, the non-DOPO flame retardant is at least one selected from the group consisting of compounds of formula (I), (II) and (III):

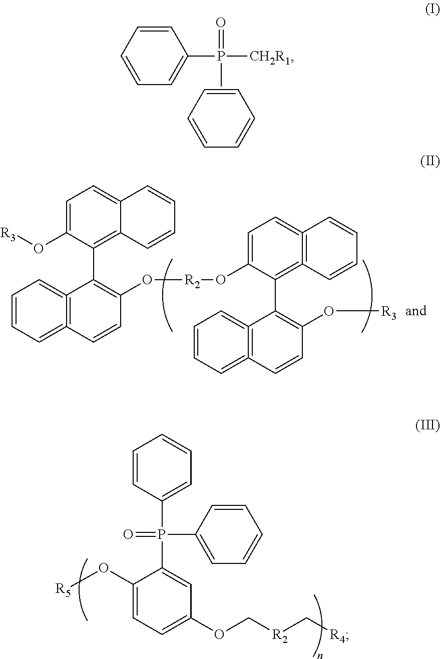

wherein R₁ is

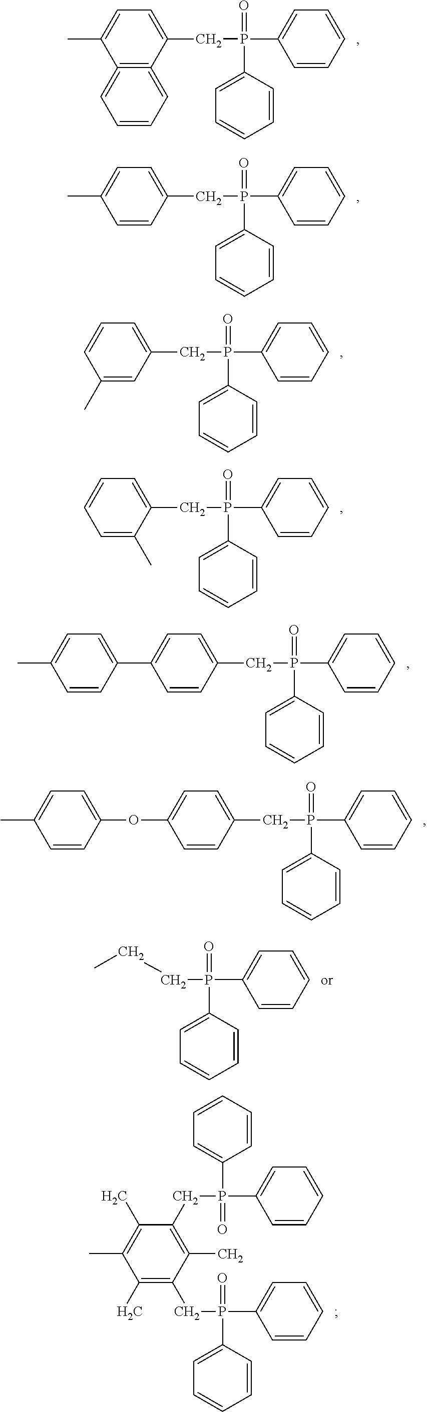

wherein R₂ is

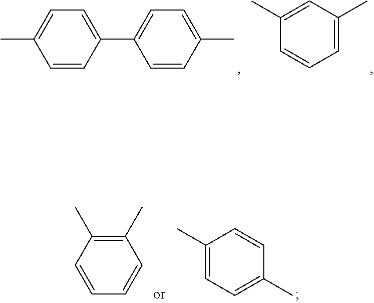

wherein R₃ is

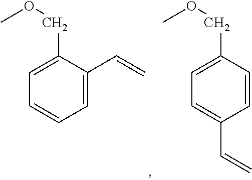

or CH₂CH₂OCH═CH₂;

wherein n is an integer from 0 to 500;

wherein R₄ is

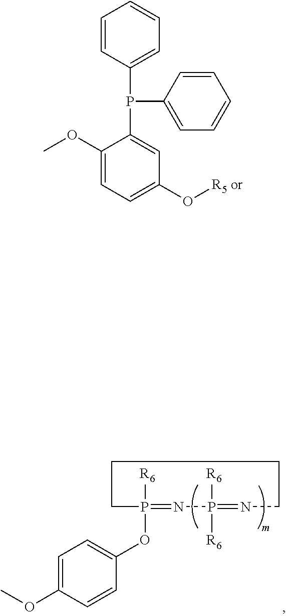

and m≥1;

wherein R₅ is

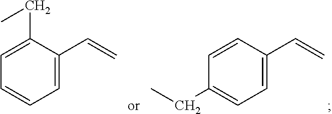

and wherein R₆ is

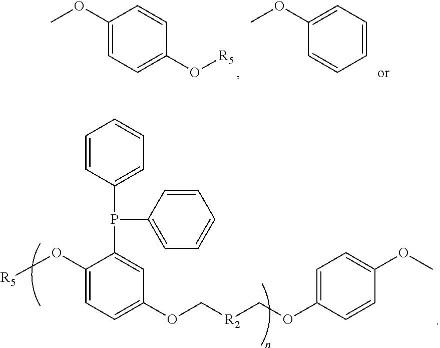

In addition, the halogen-free epoxy resin composition of the present disclosure further includes a flame retardant compound, and the flame retardant compound is at least one selected from the group consisting of resorcinol dixyl phosphate (RDXP such as PX-200), melamine polyphosphate, tris(2-carboxyethyl)phosphine (TCEP), trimethyl phosphate (TMP), tris(isopropyl chloride) phosphate, dimethyl-methyl phosphate (DMMP), bisphenol biphenyl phosphate, ammonium polyphosphate, hydroquinone-bis-(biphenyl phosphate), and bisphenol A-bis-(biphenyl phosphate).

Preferably, at least one or a mixture of the accelerating agent of the present disclosure is at least one selected from the group consisting of imidazole, metal salt, tertiary amines, or piperidines. Furthermore, the accelerating agent may be selected from boron trifluoride amine complex, 2-ethyl-4-methylimidazole (2E4MI), 2-methylimidazole (2MI), 2-phenyl-1H-imidazole (2PZ), ethyltriphenyl phosphonium chloride, triphenylphosphine (TPP), cobalt (II) acetylacetonate, 4-dimethylamino 4-dimethylaminopyridine (DMAP), low molecular weight terminal bromine-based liquid butadiene rubber (BTPB), organic metal salts such as cobalt (II) bisacetylacetonate, cobalt (III), tertiary amines such as triethylamine, tributylamine, and diazabicyclo [2.2.2] octane, and the like. More preferably, the accelerating agent is a mixture of 2-phenylimidazole and cobalt bis(acetylacetonate)(II). Specifically, the imidazole compound has better compatibility with the resin component, so that a cured product having high uniformity can be obtained.

On the other hand, the inorganic filler can increase the thermal conductivity of the halogen-free epoxy resin composition, and improve the thermal expansibility and mechanical strength. Preferably, the inorganic filler is uniformly distributed in the halogen-free epoxy resin composition. Preferably, the inorganic filler can be performed with a surface treatment by a silane coupling agent in advance. Preferably, the inorganic filler can be spherical, flake-shaped, granular, column-shaped, plate-shaped, needle-shaped, or irregularly shaped. Preferably, the inorganic filler is at least one selected from the group consisting of silicon dioxide (such as fused, non-molten, porous or hollow silica), aluminum oxide, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, Barium, magnesium carbonate, barium carbonate, mica, talc, and graphene.

In addition, the halogen-free epoxy resin composition of the present disclosure further includes a suitable solvent, such as ketones, esters, ethers, alcohols, and the like. Specifically, the solvent of the present disclosure is at least one selected from the group consisting of acetone, butanone, propylene glycol methyl ether, propylene glycol methyl ether acetate, dimethylethyl amine and cyclohexanone.

Further, the prepreg of the present disclosure includes a non-woven reinforcing material, for example, the non-woven reinforcing material can be at least one selected from the group consisting of polytetrafluoroethylene (PTFE), quartz, glass material, and liquid crystal polymers. Specifically, the non-woven reinforcing material may be sheet materials such as a non-woven PTFE mat/paper, a non-woven quartz mat/paper or a liquid crystal polymer mat/paper. For example, the ingredients may include chopped PTFE fibers, chopped glass fibers, fillers such as boron nitride, and fused silica. More specifically, the glass material may be selected from non-woven E-glass fibers, non-woven D-glass fibers, non-woven S-glass fibers, non-woven T-glass fibers, non-woven L-glass fibers, or non-woven NE glass fibers.

Specifically, there is a big difference between non-woven materials and traditional woven materials. The basic requirement of non-woven material technology is to avoid or reduce the formation of fibers into fiber collection such as yarns, and further combine the yarns into a certain geometric structure; instead, the fibers are made into single fiber distribution state to form a collection such as a fiber web. Typical non-woven materials are formed by a web structure of fibers. At the same time, in order to further increase its strength and achieve structural stability, the formed web can also be reinforced by applying adhesives, thermal bonding, fiber-to-fiber entanglement, and yarn entanglement as required. Therefore, the structure of most non-woven materials is the basic structure composed of a fiber web and a reinforcement system.

### Example E1-E6

The compositions of Examples E1 to E6 are shown in Table 1 below. A non-woven PTFE mat was used as a reinforcing material in Examples E1 to E6, which was continuously passed through a series of rollers into a gluing tank, and the tank was loaded with the halogen-free epoxy resin composition (as shown in Table 1). The reinforcing material is fully infiltrated by the halogen-free epoxy resin composition in the gluing tank, the excess halogen-free epoxy resin composition is then scraped off by a metering roller, and baked in the gluing furnace for 100 to 180 minutes so that the solvent evaporates and the resin is cured. Then, after cooling and winding, a resin substrate is formed. Further, the above resin substrate and two 18 μm copper foils were laminated in the order of copper foil, resin substrate, and copper foil, and then pressed at 220° C. for 2 hours under vacuum so that a copper foil substrate is formed.

TABLE 1

| Composition | | E1 | E2 | E3 | E4 | E5 | E6 |
|---|---|---|---|---|---|---|---|
| Epoxy resin | NPTE4000* | 40 | 40 | 40 | 30 | 30 | 30 |
| | HP-6000* | 60 | 60 | 60 | 70 | 70 | 70 |
| DOPO | DOPO-BPAN | 0 | 10 | 13 | 17 | 20 | 25 |
| modified | (DOPO-containing bisphenol | | | | | | |
| curing agent | A novolac resin) | | | | | | |
| Cyanate resin | BA230S | 45 | 40 | 33 | 36 | 30 | 25 |
| | (bisphenol cyanate resin) | | | | | | |
| Bismaleimide | BMI-5100 (bismaleimide) | 55 | 50 | 42 | 46 | 40 | 35 |
| Flame | compound of formula (I) | 50 | — | — | 10 | 25 | 15 |
| retardant | compound of formula (II) | — | 50 | — | 10 | 15 | 15 |
| | compound of formula (III) | — | — | 50 | 30 | 15 | 25 |
| Flame | PX-200 (resorcinol dixylenyl | 10 | 10 | 10 | 10 | 10 | 10 |
| retardant | phosphate) | | | | | | |
| compound | | | | | | | |
| Inorganic | Flake silicon dioxide | — | 36 | — | — | 36 | — |
| filler | Spherical silicon dioxide | 36 | — | 40 | 40 | — | 36 |
| Accelerating | Cobaltic acetylacetonate (III) | 6 | 6 | 6 | 3 | 3 | 3 |
| agent | 2E4MI | 1 | 1 | 1 | 1 | 1 | 1 |
| | (2-ethyl-4-methylimidazole) | | | | | | |
| | 2-phenylimidazole | 3 | 3 | 3 | 6 | 6 | 6 |
| Solvent | MEK (methyl ethyl ketone) | 45 | 45 | 45 | 50 | 50 | 50 |
| | DMAc (dimethylacetamide) | 30 | 30 | 30 | 20 | 20 | 20 |
| | PM (propylene glycol | 25 | 25 | 25 | 30 | 30 | 30 |
| | monomethyl ether) | | | | | | |

*NPTE4000 naphthalene based epoxy resin: : 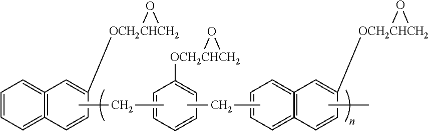
*HP-6000 naphthalene based epoxy resin (Purchased from DIC corporation,
Japan)

### Comparative Example

The compositions of Comparative Examples C1 to C6 are shown in Table 2 below. A non-woven PTFE mat was used as a reinforcing material in Examples E1 to E6, which was continuously passed through a series of rollers into a gluing tank, and the tank was loaded with the halogen-free epoxy resin composition (as shown in Table 1). The reinforcing material is fully infiltrated by the halogen-free epoxy resin composition in the gluing tank, the excess halogen-free epoxy resin composition is then scraped off by a metering roller, and baked in the gluing furnace for 120 to 180 minutes so that the solvent evaporates and the resin is cured. Then, after cooling and winding, a resin substrate is formed. Further, the above resin substrate and two 18 μm copper foils were laminated in the order of copper foil, resin substrate, and copper foil, and then pressed at 220° C. for 2 hours under vacuum so that a copper foil substrate is formed.

TABLE 2

| Composition | | C1 | C2 | C3 | C4 | C5 |
|---|---|---|---|---|---|---|
| Epoxy resin | NPTE4000 | 40 | 40 | 40 | 30 | 30 |
| | HP-6000 | 60 | 60 | 60 | 70 | 70 |
| DOPO modified | DOPO-BPAN (DOPO- | 0 | 10 | 15 | 20 | 25 |
| curing agent | containing bisphenol | | | | | |
| | A novolac resin) | | | | | |
| Cyanate resin | BA230S (bisphenol | 45 | 40 | 35 | 30 | 25 |
| | cyanate resin) | | | | | |
| Bismaleimide | BMI-5100(bismaleimide) | 55 | 50 | 45 | 40 | 35 |
| Flame retardant | compound of formula (I) | 50 | — | — | 25 | 15 |
| | compound of formula (II) | — | 50 | — | 15 | 15 |
| | compound of formula (III) | — | — | 50 | 15 | 25 |
| Flame retardant | PX-200 (resorcinol | 10 | 10 | 10 | 10 | 10 |
| compound | dixylenyl phosphate) | | | | | |
| Inorganic filler | Flake silicon dioxide | — | 33 | — | 40 | — |
| | Spherical silicon dioxide | 33 | — | 40 | — | 40 |
| Accelerating | Cobaltic | 6 | 6 | 6 | 3 | 3 |
| agent | acetylacetonate(III) | | | | | |
| | 2E4MI (2-ethyl-4- | 1 | 1 | 1 | 1 | 1 |
| | methylimidazole) | | | | | |
| | 2-phenylimidazole | 3 | 3 | 3 | 6 | 6 |
| Solvent | MEK (methyl ethyl ketone) | 45 | 45 | 45 | 50 | 50 |
| | DMAc (dimethylacetamide) | 30 | 30 | 30 | 20 | 20 |
| | PM(propylene glycol | 25 | 25 | 25 | 30 | 30 |
| | monomethyl ether) | | | | | |

[Physical Properties Analysis]

The copper foil substrate according to the above Examples E1 to E6 and Comparative Examples C1 to C5 were tested for physical properties and the test results are recorded in Table 3:

Glass transition temperature (Tg): it is determined by the differential scanning calorimetry (DSC) according to the IPC-TM-650 2.4.25C method.

Heat resistance of copper laminated substrate (T288): it is also known as “solder float result”. The heat resistance test for the copper laminated substrate is to soak the copper laminated substrate in the Tin stove at 288° C. to observe the occurrence of the “popcorn” effect, and the time elapsed until the popcorn effect occurs is measured according to the industry standard IPC-TM-650 2.4.24.1 method.

Moistened copper laminated substrate Tin test: the prepregs with copper foil is performed with the heat resistance test (T288), and the copper laminated substrate is soaked in the Tin stove at 288° C. to observe the occurrence of the popcorn effect. Here, the heat resistance test is performed according to the industry standard IPC-TM-650 2.4.24.1 method, and the time elapsed until the popcorn effect occurs is measured according to the industry standard IPC-TM-650 2.4.24.1 method.

Moisture absorption: as the copper laminated substrate will expand or adsorb moisture due to the influence of the environmental temperature and the ambient humidity, and high moisture content or high humidity will easily cause the popcorn effect or other circuit board defects of the copper laminated substrate, it is necessary to determine the absorption of water of the copper laminated substrate. Traditionally, the water absorption of the copper laminated substrate is determined by IR spectroscopy and thermo gravimetric analysis.

Peeling strength between copper foil and substrate (P/S): determined according to the standard IPC-TM-650 2.4.1 method.

Dielectric constant (Dk): determined according to the IPC-TM-650 2.5.5 method. The dielectric constant indicates the insulation property of the prepreg. The lower the dielectric constant is, the better the insulation property of the prepreg is.

Dissipation factor (Df): determined according to the IPC-TM-650 2.5.5 method. Dissipation factor indicates the absorption of a certain range of a microwave by a material under a certain temperature. According to the standards for the communicational products, a lower value of the dissipation factor represents a better performance.

Flammability test (UL94): the test of flammability is in accordance with the UL94 vertical flame test method, which determines the time of spontaneous combustion, the speed of spontaneous combustion, and the level of dripped flaming particles once the plastic specimen has been ignited. According to the classifications of the flammability, the testing results are rated from lowest (least flame-retardant) to highest (most flame-retardant) as HB, V-2, V-1, V-0 . . . and 5V, and the anti-flammability of prepregs is determined in accordance with the classifications. The prepreg to be tested is burnt on the fire source vertically and the test procedure lasts for ten seconds, and the steps are as follows: Step 1: burning the prepreg for 10 seconds, and then moving the prepreg away from the fire source while simultaneously beginning to count the time period (T1) that the prepreg continues to burn after being removed from the fire source; Step 2: burning the prepreg for 10 seconds again after the fire source of Step 1 is extinguished, then moving the prepreg away while simultaneously beginning to count the time period (T2) that the prepreg continues to burn after being removed from the fire source; Step 3: repeating step 1 and step 2, and calculating the mean value of T1 and T2; and Step 4: summing the mean value of T1 and T2. According to the V-0 classification defined in UL 94, neither of the mean value of T1 and T2 is larger than 10 seconds and the sum of the mean value of T1 and T2 is no more than 50 seconds, indicating that the prepreg complies with the V-0 classification.

X or Y axis coefficient of thermal expansion (CTE) of substrate insulating layer: measured according to the IPC-TM-650-2.4.24 method.

The storage modulus of the substrate insulating layer: measured by DMA instrument to be greater than or equal to 5000 MPa at about 250° C., according to the IPC-TM-650-2.4.24.2 method.

TABLE 3

| Condition | Method | E1 | E2 | E3 | E4 | E5 | E6 | C1 | C2 | C3 | C4 |
|---|---|---|---|---|---|---|---|---|---|---|---|
| Glass transition | DSC | 246 | 249 | 251 | 248 | 249 | 250 | 168 | 163 | 165 | 166 |
| temperature (Tg) | | | | | | | | | | | |
| Heat resistance of | TMA | >60 | >60 | >60 | >60 | >60 | >60 | >30 | >30 | >50 | >60 |
| copper laminated | | | | | | | | | | | |
| substrate (T288) | | | | | | | | | | | |
| PCT (dip minute) | 1 hr/ | >60 | >60 | >60 | >60 | >60 | >60 | >60 | >60 | >60 | >60 |
| | 120° C. | | | | | | | | | | |
| Water | PCT/121° | 0.39 | 0.41 | 0.4 | 0.4 | 0.42 | 0.4 | 0.53 | 0.55 | 0.58 | 0.6 |
| absorption % | C./1 hr | | | | | | | | | | |
| P/S (lb/min) | Hoz Cu | 7.9 | 7.7 | 8 | 7.9 | 7.8 | 8.1 | 5.2 | 5.8 | 5.5 | 6.1 |
| | foil | | | | | | | | | | |
| Dₖ@10 GHz | 10 GHz | 3.6 | 3.65 | 3.64 | 3.7 | 3.68 | 3.7 | 4.54 | 4.6 | 4.68 | 4.63 |
| D_{f}@10 GHz | 10 GHz | 0.0056 | 0.0058 | 0.0059 | 0.0058 | 0.0059 | 0.0059 | 0.0089 | 0.009 | 0.0092 | 0.0097 |
| Flammability | UL94 | V-0 | V-0 | V-0 | V-0 | V-0 | V-0 | V-0 | V-0 | V-0 | V-0 |
| CTE(α1, X-axis, | TMA | 5.8 | 5.4 | 5.7 | 5.6 | 5.2 | 5.5 | 13 | 15 | 16 | 15 |
| ppm/° C.) | | | | | | | | | | | |
| CTE(α1, Y-axis, | TMA | 4.2 | 4.3 | 4 | 4.2 | 4.3 | 4.1 | 14 | 15 | 15 | 16 |
| ppm/° C.) | | | | | | | | | | | |
| Storage modulus | DMA | 21.62/ | 22.05/ | 22.33/ | 22.19/ | 21.82/ | 22.28/ | 13.62/ | 14.55/ | 12.63/ | 13.88/ |
| (GPa, DMA, @50/ | X/Y axis | 14.42 | 14.09 | 14.35 | 14.27 | 14.21 | 14.30 | 4.46 | 5.09 | 5.20 | 4.24 |
| 260° C.) Condition | Method | | | | | | | | | | |

In conclusion, one of the advantages of the present disclosure is that the present disclosure can provide better glass transition temperature and be skew-free by the technical feature of using “a non-woven reinforcing material, having a dielectric constant of from 1.5 to 4.8 and a dissipation factor at 10 GHz below 0.003” and “45 to 65 parts by weight of non-DOPO flame retardant”.

Furthermore, the halogen-free epoxy resin composition of the present disclosure can improve on the heat resistance and reduce the coefficient of thermal expansion of the halogen-free epoxy resin composition by using the naphthalene based epoxy resin. In addition, the DOPO modified curing agent not only provides good thermal stability and low dielectric properties, but also enhances the effectiveness of flame retardants. Furthermore, the non-DOPO flame retardant can avoid increasing the Dk and Df of the halogen-free epoxy resin composition.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A prepreg, comprising:
a non-woven reinforcing material having a dielectric constant of from 1.5 to 4.8 and a dissipation factor at 10 GHz below 0.003; and
a halogen-free epoxy resin composition including:
(a) 100 parts by weight of a halogen-free naphthalene based epoxy resin;
(b) 10 to 25 parts by weight of DOPO modified curing agent;
(c) 25 to 45 parts by weight of cyanate resin;
(d) 35 to 60 parts by weight of bismaleimide;
(e) 45 to 65 parts by weight of non-DOPO flame retardant; and
(f) 0.5 to 15 parts by weight of accelerating agent;
wherein the non-woven reinforcing material is impregnated with the halogen-free epoxy resin composition, and is partially cured.

2. The prepreg according to claim 1, wherein the halogen-free naphthalene based epoxy resin is at least one selected from the group consisting of di-naphthalene based epoxy resin, tetra-naphthalene based epoxy resin, and oxazolidone-containing di-naphthalene based epoxy resin.

3. The prepreg according to claim 1, wherein the DOPO modified curing agent is at least one selected from the group consisting of DOPO-hydroquinone resin, DOPO-naphthalene diol resin, DOPO-novolak resin, and DOPO-bisphenol novolac resin; wherein the DOPO-containing bisphenol novolac resin is at least one selected from the group consisting of DOPO-containing bisphenol A novolac resin, DOPO-containing bisphenol F novolac resin, and DOPO-containing bisphenol S novolac resin.

4. The prepreg according to claim 1, wherein the bismaleimide is at least one selected from the group consisting of bis(4-phenylmaleimide)methane, 2,2-bis(4-(4-phenoxymaleimide)-phenyl)propane, bis(3,5-dimethyl-4-phenylmaleimide)methane, bis(3-ethyl-5-methyl-4-phenylmaleimide), and (3,5-diethyl-4-phenylmaleimide)methane.

5. The prepreg according to claim 1, wherein the non-DOPO flame retardant is at least one selected from the group consisting of compounds of formula (I), (II) and (III): 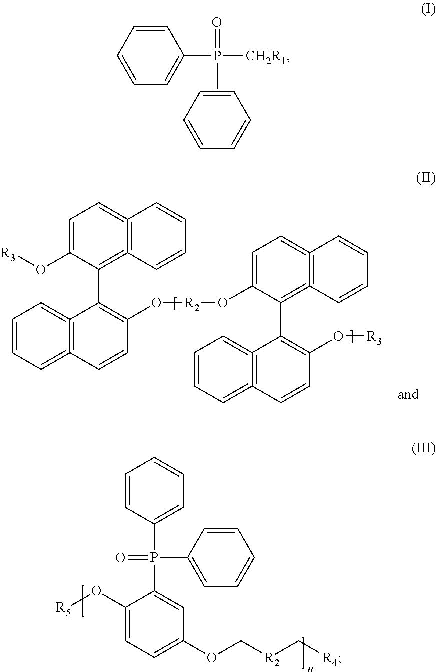
wherein R₁ is 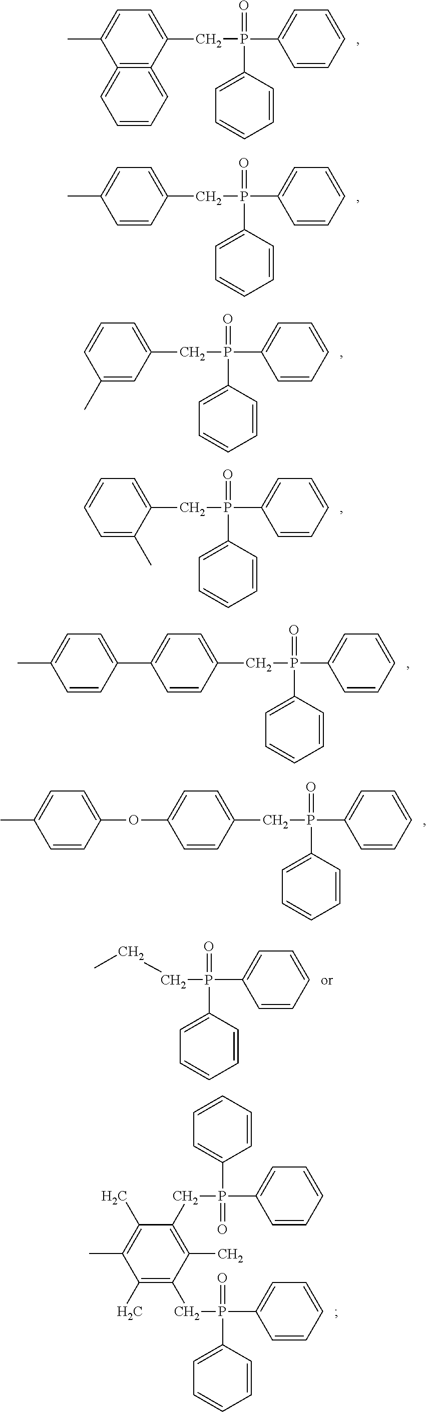
wherein R₂ is 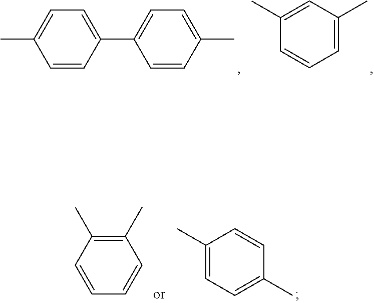
wherein R₃ is 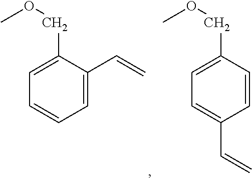
or CH₂CH₂OCH═CH₂;
wherein n is an integer from 0 to 500;
wherein R₄ is 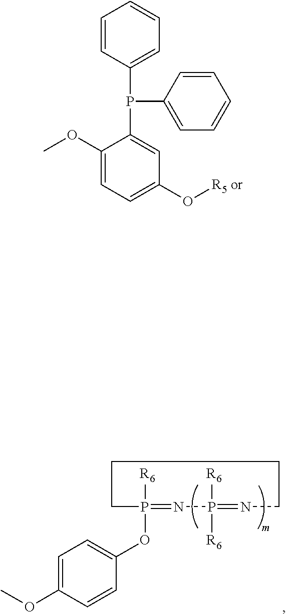
and m≥1;
wherein R₅ is 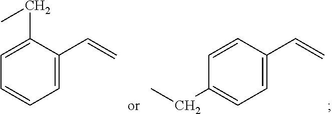
and wherein R₆ is

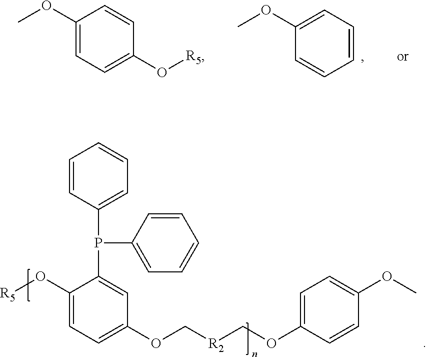

6. The prepreg according to claim 1, further comprising a flame retardant compound, wherein the flame retardant compound is at least one selected from the group consisting of resorcinol dixyl phosphate, melamine polyphosphate, tris(2-carboxyethyl)phosphine, trimethyl phosphate, tris (isopropyl chloride)phosphate, Dimethyl-methyl phosphate, bisphenol biphenyl phosphate, ammonium polyphosphate, hydroquinone-bis-(biphenyl phosphate), and bisphenol A-bis-(biphenyl phosphate).

7. The prepreg according to claim 1, wherein the accelerating agent is at least one selected from the group consisting of boron trifluoride amine complex, 2-ethyl-4-methylimidazole, 2-methylimidazole, 2-phenylimidazole, ethyltriphenylphosphonium chloride (II), 4-dimethylaminopyridine, liquid bromine-terminated butadiene rubbers, cobalt (II) bisacetylacetonate, cobalt (III) triethoxysilane, triethylamine, tributylamine, and diazabicyclo [2.2.2] octane.

8. The prepreg according to claim 1, further comprising an inorganic filler, wherein the inorganic filler is at least one selected from the group consisting of silicon dioxide, aluminum oxide, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, barium, magnesium carbonate, barium carbonate, mica, talc, and graphene.

9. The prepreg according to claim 1, further comprising a solvent, wherein the solvent is at least one selected from the group consisting of acetone, butanone, propylene glycol methyl ether, propylene glycol methyl ether acetate, dimethylethyl amine, and cyclohexanone.

10. The prepreg according to claim 1, wherein the non-woven reinforcing material is at least one selected from the group consisting of polytetrafluoroethylene, liquid crystal polymer, quartz, and glass.

11. A laminated board, comprising:
a resin substrate including a plurality of cured prepreg;
at least one metal foil layer disposed on at least one surface of the resin substrate, wherein the prepreg includes a non-woven reinforcing material having a dielectric constant of from 1.5 to 4.8 and a dissipation factor at 10 GHz below 0.003; and
a halogen-free epoxy resin composition including:
(a) 100 parts by weight of a halogen-free naphthalene based epoxy resin;
(b) 10 to 25 parts by weight of DOPO modified curing agent;
(c) 25 to 45 parts by weight of cyanate resin;
(d) 35 to 60 parts by weight of bismaleimide;
(e) 45 to 65 parts by weight of non-DOPO flame retardant; and
(f) 0.5 to 15 parts by weight of accelerating agent;
wherein the non-woven reinforcing material is impregnated with the halogen-free epoxy resin composition, and is partially cured.

12. A printed circuit board, formed by patterning the metal foil layer of the laminated board as claimed in claim 11.
